(19) United States
(12) Patent Application Publication
(10) Pub. No.: US 2024/0074180 A1
(43) Pub. Date: Feb. 29, 2024

(54) THREE-DIMENSIONAL NAND MEMORY DEVICE AND METHOD OF FORMING THE SAME

(71) Applicant: Yangtze Memory Technologies Co., Ltd., Wuhan (CN)

(72) Inventors: Shasha LIU, Wuhan (CN); Tianhui ZHANG, Wuhan (CN); Min YANG, Wuhan (CN); Xiaoming MAO, Wuhan (CN); Zongliang HUO, Wuhan (CN)

(73) Assignee: Yangtze Memory Technologies Co., Ltd., Wuhan (CN)

(21) Appl. No.: 17/896,731

(22) Filed: Aug. 26, 2022

(51) Int. Cl. H01L 27/11582

(52) U.S. Cl. CPC H01L 27/11582

(57) ABSTRACT

A semiconductor device includes a first stack of alternating first word line layers and first insulating layers over a semiconductor layer. The first stack includes a first array region and a first staircase region adjacent to the first array region. The semiconductor device includes a second stack of alternating second word line layers and second insulating layers, where the second stack includes a second array region over the first array region and a second staircase region adjacent to the second array region and over the first staircase region. The first stack further includes a first transition layer over the first word line layers. The first transition layer includes a first dielectric portion in the first array region that surrounds the first channel structure and a first conductive portion. The first transition layer is disposed between two adjacent first insulating layers of the first insulating layers.

### BACKGROUND

As critical dimensions of devices in integrated circuits shrink to the limits of common memory cell technologies, designers have been looking to techniques for stacking multiple planes of memory cells to achieve greater storage capacity, and to achieve lower costs per bit. A 3D NAND memory device is an exemplary device of stacking multiple planes of memory cells to achieve greater storage capacity, and to achieve lower costs per bit. The 3D NAND memory device can include a lower stack of alternating lower insulating layers and lower word line layers over a substrate and an upper stack of alternating upper insulating layers and upper word line layers over the lower stack. A plurality of lower channel structures can extend from the substrate and through the lower stack. A plurality of upper channel structures can extend from the plurality of lower channel structures and through the upper stack.

### SUMMARY

The present disclosure describes embodiments generally related to a dual deck structure of a 3D NAND memory device that has an improved overlap margin between an upper deck and a lower deck of the dual deck structure.

According to an aspect of the disclosure, a semiconductor device is provided. The semiconductor device can include a first stack of alternating first word line layers and first insulating layers over a semiconductor layer, the first stack including a first array region and a first staircase region adjacent to the first array region; a first channel structure extending from the semiconductor layer and through the first array region of the first stack; a second stack of alternating second word line layers and second insulating layers over the first stack, the second stack including a second array region over the first array region and a second staircase region adjacent to the second array region and over the first staircase region; and a second channel structure extending from the first channel structure and through the second array region of the second stack, wherein the first stack further includes a first transition layer over the first word line layers, the first transition layer including a first dielectric portion in the first array region that surrounds the first channel structure and a first conductive portion, the first transition layer being disposed between two adjacent first insulating layers of the first insulating layers.

In an embodiment, the first conductive portion can be in the first staircase region. In another embodiment, the first conductive portion can be in the first array region. In some embodiments, the semiconductor device can further include a slit structure extending through the first stack and the second stack in a vertical direction perpendicular to the semiconductor layer. For example, the first transition layer can further include a second conductive portion positioned in the first array region and arranged between the first dielectric portion and the slit structure, the slit structure can include protrusions that extend to and contact the first transition layer, the first word line layers, and the second word line layers in a horizontal direction parallel to the semiconductor layer. As another example, the first transition layer can further include a third conductive portion positioned in the first array region and sandwiched by the first dielectric portion. In an example, the slit structure can include protrusions that extend to the second dielectric portion of the first transition layer in the horizontal direction.

In an embodiment, the slit structure can include protrusions that extend to the first dielectric portion of the first transition layer in the horizontal direction. In another embodiment, the first stack can further include a second transition layer that is positioned between the first transition layer and the first word line layers, the second transition layer including a second dielectric portion under the first dielectric portion in the first array region that surrounds the first channel structure and a first conductive portion in the first staircase region. In some embodiments, the first dielectric portion of the first transition layer can include nitride. For example, the first dielectric portion of the first transition layer can be doped with one of carbon, boron and phosphorous.

According to an aspect of the disclosure, a method is also provided. The method can include: forming a first stack of alternating first sacrificial layers and first insulating layers over a semiconductor layer, the first stack including a first array region and a first staircase region adjacent to the first array region, the first sacrificial layers including an uppermost first sacrificial layer and other first sacrificial layers; forming a first region in the uppermost first sacrificial layer; forming a second stack of alternating second sacrificial layers and second insulating layers over the first stack, the second stack including a second array region over the first array region and a second staircase region adjacent to the second array region and over the first staircase region; and replacing a second region of the uppermost first sacrificial layer, the other first sacrificial layers, and the second sacrificial layers with a conductive material to form a first transition layer, first word line layers under the first transition layer in the first stack, and second word line layers in the second stack, respectively, wherein the first transition layer includes the first region in the first array region and a first conductive region.

In an embodiment, the first conductive region can be in the first staircase region. In another embodiment, the first conductive region can be in the first array region. For example, the first stack can further include a secondary first sacrificial layer between the uppermost first sacrificial layer and the other first sacrificial layers, and the method can further includes: forming a third region in the secondary first sacrificial layer, the third region being positioned under the first region and arranged in the first array region; and replacing a fourth region of the secondary first sacrificial layer with the conductive material to form a second transition layer, the second transition layer including the third region in the first array region and a second conductive region. As another example, the method can further include forming a first channel structure extending from the semiconductor layer and through the first array region of the first stack such that the first channel structure extends through the first and third regions, and forming a second channel structure extending from the first channel structure and through the second array region of the second stack.

In an embodiment, the replacing the second region of the uppermost first sacrificial layer, the other first sacrificial layers, the second sacrificial layers, and the fourth region of the secondary first sacrificial layer can further include forming a trench opening having a bottom extending into the semiconductor layer, removing the second region of the uppermost first sacrificial layer, the fourth region of the secondary first sacrificial layer, the other first sacrificial layers, and the second sacrificial layers such that spaces are formed between adjacent insulating layers of the first insulating layers and the second insulating layers, and depositing the conductive material in the spaces to form the first conductive region of the first transition layer, the second conductive region of the second transition layer, the first word line layers in the first stack, and the second word line layers in the second stack, the conductive material further being deposited along sidewalls of the trench opening and over the bottom of the trench opening. In another embodiment, the method can further include: removing the conductive material deposited along the sidewalls and over the bottom of the trench opening to form a slit opening, and recessing the first transition layer, the second transition layer, the first word line layers, and the second word line layers from the sidewalls of the trench opening in a horizontal direction parallel to the semiconductor layer such that the slit opening extends to the first transition layer, the second transition layer, the first word line layers, and the second word line layers; and depositing a dielectric material to fill in the slit opening to form a slit structure. For example, the slit structure can extend through the first insulating layers and the second insulating layers, and further include protrusions that extend to and contact the first region of the first transition layer, the third region of the second transition layer, the first word line layers, and the second word line layers in the horizontal direction.

In an embodiment, the replacing the second region of the uppermost first sacrificial layer and the fourth region of the secondary first sacrificial layer can further include: depositing the conductive material in the spaces to form (i) a third conductive region of the first transition layer in the first array region and arranged between the first region and the slit structure, and (ii) a fourth conductive region of the second transition layer in the first array region and arranged between the third region and the slit structure, wherein the slit structure includes protrusions that extend to and contact the third conductive region of the first transition layer and the fourth conductive region of the second transition layer in the horizontal direction. In another embodiment, the replacing can further include: depositing the conductive material in the spaces to form (i) a fifth conductive region of the first transition layer in the first array region such that the first region is arranged between the third and fifth conductive regions, and (ii) a sixth conductive region of the second transition layer in the first array region such that the third region is arranged between the fourth and sixth conductive regions. In other embodiments, the forming the first region and the third region can further comprise: forming a mask layer over a top surface of the first stack, the mask layer including a pattern to uncover an implant region of the top surface of the first stack in the first array region; and performing an implantation process to inject dopants into the uppermost first sacrificial layer and the secondary first sacrificial layer through the implant region of the first stack to form the first region and the third region. In various embodiments, the implant region of the first stack can include one of (i) a first region around the first channel structure, (ii) a second region uncovering the slit structure, and (iii) a third region uncovering the first array region.

According to an aspect of the disclosure, a memory system device is also provided. The memory system device can include a control circuitry coupled with a memory device, and the memory device, the memory device including: first stack of alternating first word line layers and first insulating layers over a semiconductor layer, the first stack including a first array region and a first staircase region adjacent to the first array region; a first channel structure extending from the semiconductor layer and through the first array region of the first stack; a second stack of alternating second word line layers and second insulating layers over the first stack, the second stack including a second array region over the first array region and a second staircase region adjacent to the second array region and over the first staircase region; and a second channel structure extending from the first channel structure and through the second array region of the second stack, wherein the first stack further includes a first transition layer over the first word line layers, the first transition layer including a first dielectric portion in the first array region that surrounds the first channel structure and a first conductive portion, the first transition layer being disposed between two adjacent first insulating layers of the first insulating layers.

### BRIEF DESCRIPTION OF THE DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A is a first cross-sectional view of a first 3D NAND memory device, in accordance with exemplary embodiments of the disclosure.

FIG. 1B is a second cross-sectional view of the first 3D NAND memory device, in accordance with exemplary embodiments of the disclosure.

FIG. 2A is a first cross-sectional view of a second 3D NAND memory device, in accordance with exemplary embodiments of the disclosure.

FIG. 2B is a second cross-sectional view of the second 3D NAND memory device, in accordance with exemplary embodiments of the disclosure.

FIG. 2C is a first cross-sectional view of a third 3D NAND memory device, in accordance with exemplary embodiments of the disclosure.

FIGS. 3-14 are cross-sectional views of various intermediate steps of manufacturing the first and second 3D NAND memory devices, in accordance with exemplary embodiments of the disclosure.

FIGS. 15A-15C are exemplary cross-sectional views of initial steps of manufacturing various 3D NAND memory devices, in accordance with exemplary embodiments of the disclosure.

FIGS. 16A-16D are cross-sectional views of exemplary additional steps of manufacturing a first 3D NAND memory device with doped dielectric regions in word line layers, in accordance with exemplary embodiments of the disclosure.

FIGS. 17A-17D are cross-sectional views of exemplary additional steps of manufacturing a second 3D NAND memory device with doped dielectric regions in word line layers, in accordance with exemplary embodiments of the disclosure.

FIGS. 18A-18D are cross-sectional views of exemplary additional steps of manufacturing a third 3D NAND memory device with doped dielectric regions in word line layers, in accordance with exemplary embodiments of the disclosure.

FIG. 19 shows a block diagram of a memory system device according to some exemplary embodiments of the disclosure.

FIG. 20 is a flowchart of a process for manufacturing a 3D NAND memory device, in accordance with exemplary embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features may be in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A 3D NAND memory device can include a lower deck and an upper deck. The lower deck can include a lower stack of alternating lower word line layers and lower insulating layers over a substrate. The lower stack can include a lower array region and a lower staircase region that is adjacent to the lower array region. A plurality of lower channel structures can extend from the substrate and through the lower word line layers and the lower insulating layers in the lower array region. The upper deck can include an upper stack of alternating upper word line layers and upper insulating layers over the lower stack. The upper stack can include an upper array region over the lower array region, and an upper staircase region adjacent to the upper array region and over the lower staircase region. A plurality of upper channel structures can extend from the lower channel structures and through the upper word line layers and the upper insulating layers in the upper array region. Each of the upper channel structures can extend from, or be otherwise connected to, a respective lower channel structure. Thus, a good alignment (or overlap) between the upper channel structures and the lower channel structures is required.

In a related example, when a poor overlap occurs between an upper channel structure and a lower channel structure, the upper channel structure may extend past the lower channel structure and extend into an adjacent lower word line layer to cause an enlarged top critical dimension (CD) of the lower channel structure, which can result in voids in the adjacent word line layer and cause a word line leakage.

In the disclosure, dielectric regions can be formed in the lower word line layers (e.g., an uppermost lower word line layer) that are positioned at an interface (or joint) area of the upper channel structures and the lower channel structures. When the poor overlap occurs between the upper channel structure and the lower channel structure, the upper channel structure can extend into the dielectric regions of the adjacent lower word line layers rather than conductive regions of the adjacent lower word line layers. Thus, voids in the adjacent word lines can be prevented. Accordingly, an electrical leakage in the adjacent lower word line layers or an electrical short between the upper channel structure and the adjacent lower word line layers can be prevented.

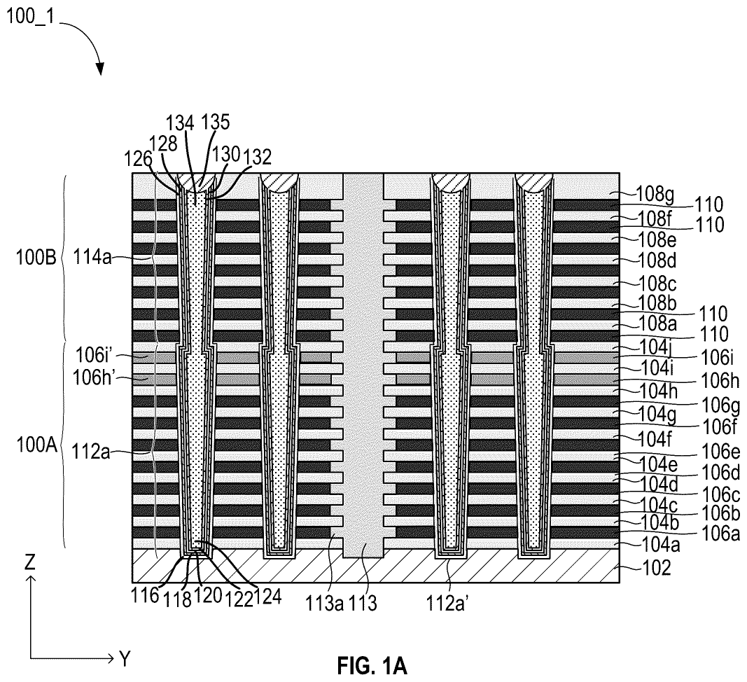

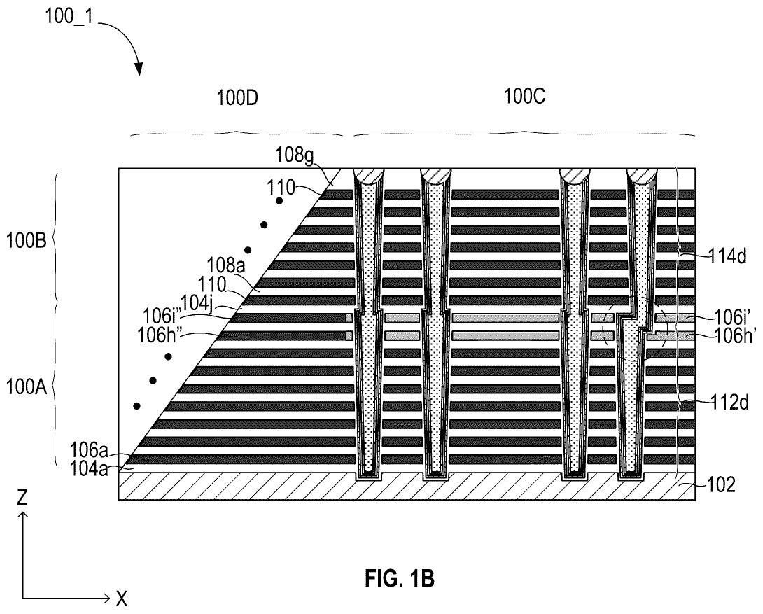

FIG. 1A is a cross-sectional view of an array region of a 3D NAND memory device (or device) 100_1, in accordance with exemplary embodiments of the disclosure. As shown in FIG. 1A, the device 100_1 can have a dual deck structure that includes a lower deck over a substrate (or a semiconductor layer) 102 and an upper deck over the lower deck. The lower deck can include a lower stack 100A of alternating lower word line layers 106a-106i and lower insulating layers 104a-104j over the substrate 102, and a plurality of lower channel structures (e.g., 112a) extending from the substrate 102 and through the lower insulating layers 104a-104j and the lower word line layers 106a-106i. The upper deck can include an upper stack 100B of alternating upper word line layers 110 and upper insulating layers 108a-108g over the lower stack 100A, and a plurality of upper channel structures (e.g., 114a) extending from the lower channel structures and through the upper word line layers 110 and the upper insulating layers 108a-108g. It should be noted that FIG. 1A is merely an example, and the device 100 can include any number of lower insulating layers, lower word line layers, upper insulating layers, and upper word line layers.

In the device 100_1, an uppermost lower word line layer 106i can function as a first transition layer positioned at a joint area of the upper channel structures and the lower channel structures. The uppermost lower word line layer 106i can include a first dielectric portion 106i′ through which the lower channel structures (e.g., 112a) can extend. In addition, a second lower word line layer 106h under the uppermost word line layer 106i can function as a second transition layer positioned at the joint area of the upper channel structures and the lower channel structures. The second lower word line layer 106h can include a second dielectric portion 106h′ through which the lower channel structures (e.g., 112a) can extend. Thus, the lower channel structures can be surrounded by the first dielectric portion 106i′ and the second dielectric portion 106h′. In some embodiments, the lower word line layers 106a-106g and the upper word line layers 110 can be made of a conductive material, such as W or polysilicon. The first dielectric portion 106i′ and the second dielectric portion 106h′ can be made of SiN or other suitable dielectric materials. In some embodiments, the first dielectric portion 106i′ and the second dielectric portion 106h′ can include nitride such as silicon nitride. In other embodiments, the first dielectric portion 106i′ and the second dielectric portion 106h′ can further be doped with one of carbon, boron, and phosphorous. The lower insulating layers 104a-104j and the upper insulating layers 108a-108g can be made of SiO. Although two transition layers are illustrated in FIG. 1A, it should be noted that one transition layer or more than two transition layers can be provided in other embodiments.

The device 100_1 can include a slit structure 113 extending from the substrate 102 and through the lower stack 100A and the upper stack 100B in a vertical direction (e.g., Z direction) perpendicular to the substrate 102. The slit structure 113 can further include protrusions 113a that extend to and contact the lower word line layers 106a-106g, the first dielectric portion 106i′, the second dielectric portion 106h′, and the upper word line layers 110 in a horizontal direction (e.g., Y direction) parallel to the substrate 102. In some embodiments, the slit structure 113 can be made of a same dielectric material as the lower insulating layers 104a-104j and the upper insulating layers 108a-108g, such as SiO.

The lower channel structure 112a can have a tapered profile and include a bottom surface 112a′ positioned in the substrate 102 and a top surface in contact with a respective upper channel structure (e.g., 114a), where the top surface can have a larger critical dimension (CD) than the bottom surface. The lower channel structure 112a can have a first block layer 116 formed along sidewalls and over the bottom surface (e.g., 112a′) of the corresponding lower channel structure, a first charge trapping layer 118 formed over the first block layer 116, a first tunneling layer 120 formed over the first charge trapping layer 118, and a first channel layer 122 formed over the first tunneling layer 120. The lower channel structure 112a can also include a first isolation layer 124 formed over the first channel layer 122.

The upper channel structure 114a can also have a tapered profile and include a bottom surface on the lower channel structure 112a and a top surface level with a top surface of an uppermost upper insulating layer 108g, where the top surface of the corresponding upper channel structure 114a can have a larger CD than the bottom surface of the corresponding upper channel structure 114a, and the bottom surface of the corresponding upper channel structure 114a can have a smaller CD than the top surface of the lower channel structure 112a. The upper channel structure 114a can have a second block layer 126 formed along sidewalls and in contact with the first block layer 116, a second charge trapping layer 128 formed over the second block layer 126 and in contact with the first charge trapping layer 118, a second tunneling layer 130 formed over the second charge trapping layer 128 and in contact with the first tunneling layer 120, and a second channel layer 132 formed over the second tunneling layer 130 and in contact with the first channel layer 122. The upper channel structures 114a can further include a second isolation layer 134 formed along sidewalls of the second channel layer 132 and over the first isolation layer 124, and a channel contact 135 in contact with the second channel layer 132 and surrounded by the uppermost upper insulating layer 108g.

FIG. 1B is a cross-sectional view of an array region 100C and a staircase region 100D of the device 100_1, in accordance with exemplary embodiments of the disclosure. As shown in FIG. 1B, in the lower stack 100A of the device 100_1, the uppermost lower word line layer 106i can include the first dielectric portion 106i′ in the array region 100C, and a first conductive portion 106i″ in the staircase region 100D. The second lower word line layer 106h can include the second dielectric portion 106h′ in the array region 100C, and a second conductive portion 106h″ in the staircase region 100D.

As shown in FIG. 1B, the uppermost lower word line layer 106i can function as a first transition layer, and the second lower word line layer 106h can function as a second transition layer. The first transition layer 106i and the second transition layer 106h can be disposed at an interface (or joint) area between the upper channel structures and the lower channel structures and include dielectric regions (e.g., 106i′ and 106h′). When a poor overlap occurs between an upper channel structure 114d and a lower channel structure 112d, the upper channel structure 114d can extend into the dielectric regions (e.g., 106i′ and 106h′) of the adjacent lower word line layers. Accordingly, an electrical leakage in the adjacent lower word line layers or an electrical short between the upper channel structure and the adjacent lower word line layers can be prevented.

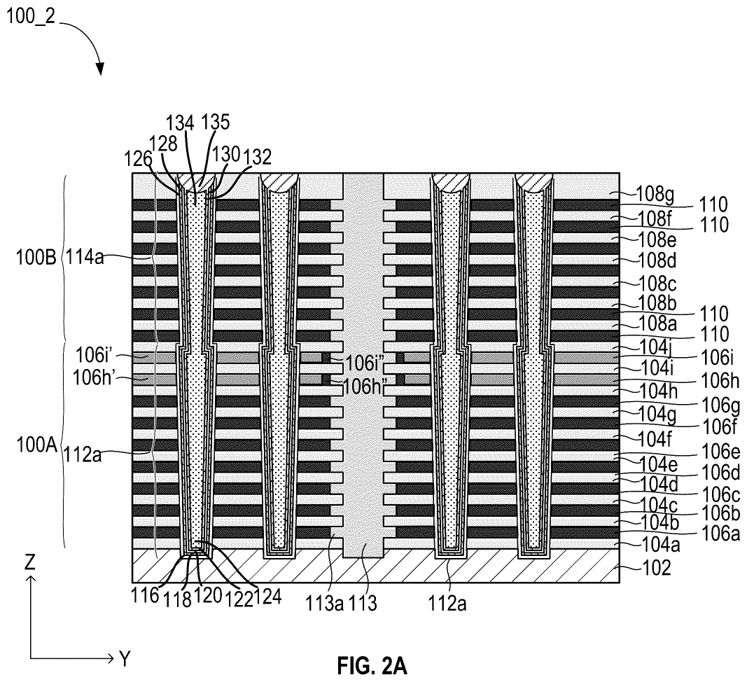

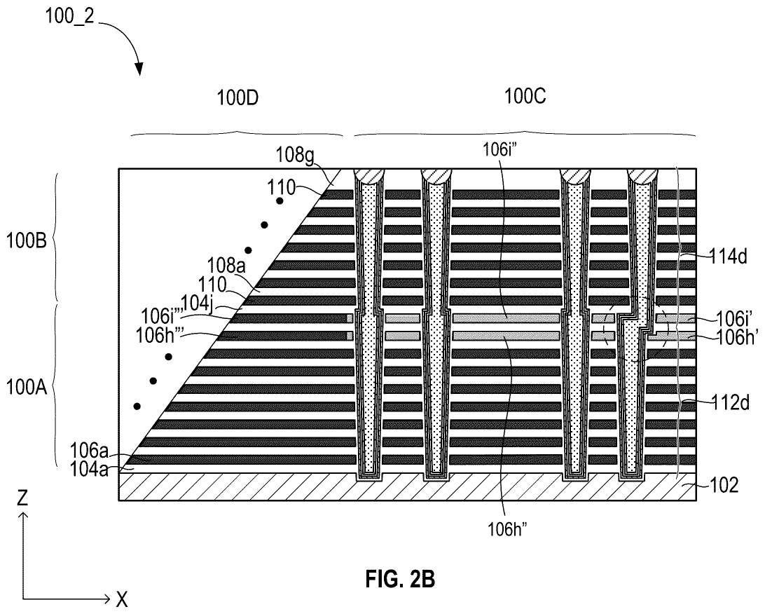

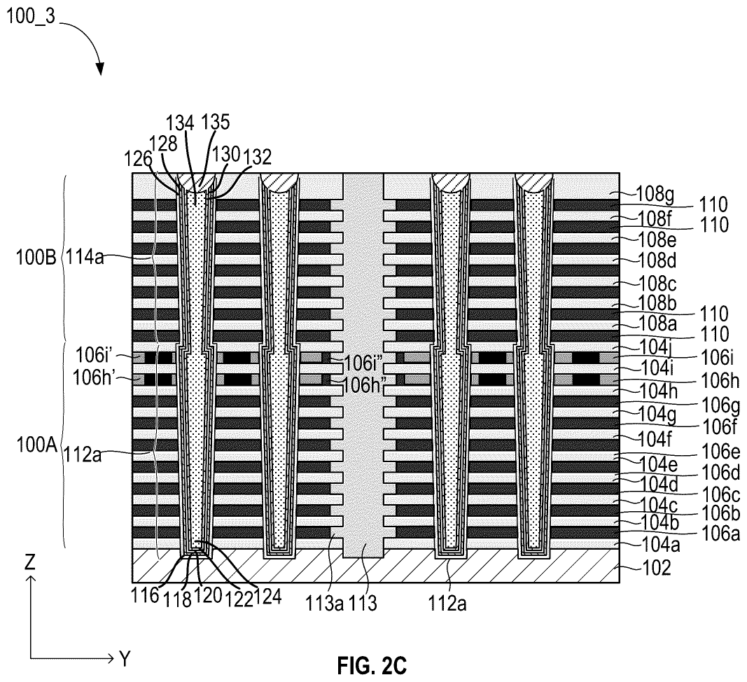

FIG. 2A is a cross-sectional view of an array region of a 3D NAND memory device (or device) 100_2, in accordance with exemplary embodiments of the disclosure. Compared to the device 100_1 in FIG. 1A, an uppermost lower word line layer 106i in the device 100_2 can include a first conductive portion 106i″ positioned in the lower array region and arranged between a first dielectric portion 106i′ and the slit structure 113. In addition, a second lower word line layer 106h under the uppermost lower word line layer 106i can include a first conductive portion 106h″ positioned in the lower array region and arranged between a second dielectric portion 106h′ and the slit structure 113. The protrusions 113a of the slit structure 113 accordingly extends to the first conductive portion 106i″ and the first conductive portion 106h″ in the horizontal direction (e.g., Y direction).

FIG. 2B is a cross-sectional view of an array region 100C and a staircase region 100D of the device 100_2, in accordance with exemplary embodiments of the disclosure. As shown in FIG. 2B, in the lower stack 100A of the device 100_2, the uppermost lower word line layer 106i can include the first dielectric portion 106i′ in the array region 100C, the first conductive portion 106i″ positioned in the lower array region 100C and arranged between the first dielectric portion 106i′ and the slit structure 113, and a second conductive portion 106i′″ in the staircase region 100D. The second lower word line layer 106h can include the second dielectric portion 106h′ in the array region 100C, and the first conductive portion 106h″ positioned in the lower array region 100C and arranged between the second dielectric portion 106h′ and the slit structure 113, and a second conductive portion 106h′ in the staircase region 100D.

FIG. 2C is a cross-sectional view of an array region of a 3D NAND memory device (or device) 100_3, in accordance with exemplary embodiments of the disclosure. Compared to the device 100_2 in FIG. 2A, an uppermost lower word line layer 106i in the device 100_3 can include a first conductive portion 106i″ positioned in the lower array region, and arranged between a first dielectric portion 106i′ and the slit structure 113 and sandwiched by the first dielectric portion 106i′. In addition, a second lower word line layer 106h under the uppermost lower word line layer 106i can include a first conductive portion 106h″ positioned in the lower array region, and arranged between a second dielectric portion 106h′ and the slit structure 113 and sandwiched by the second dielectric portion 106h′. The protrusions 113a of the slit structure 113 accordingly extends to the first conductive portion 106i″ and the first conductive portion 106h″ in the horizontal direction (e.g., Y direction).

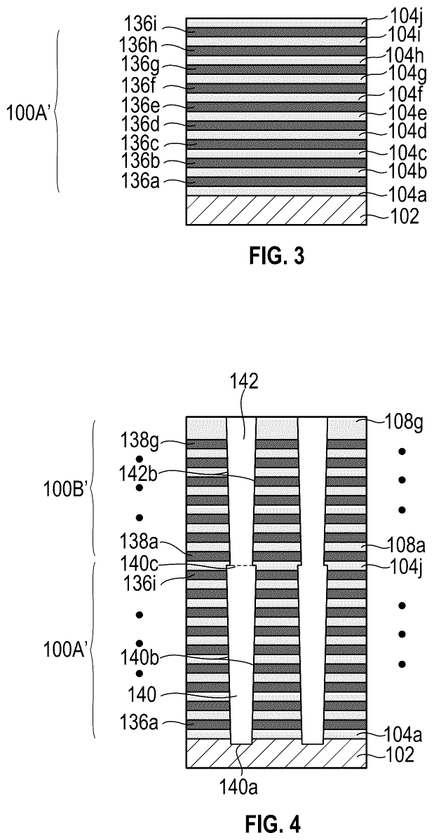

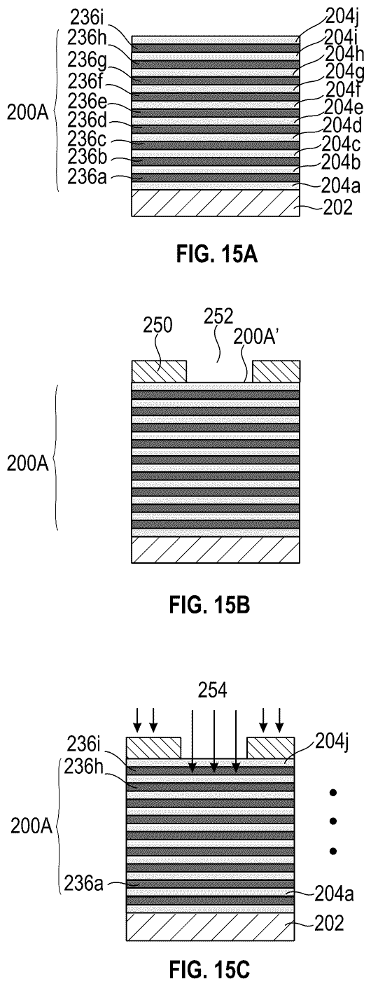

FIGS. 3-12 are perspective views of various intermediate steps of forming, or otherwise manufacturing the first device 100_1 and the second device 100_2, in accordance with exemplary embodiments of the disclosure. In FIG. 3, a lower stack 100A′ of alternating lower sacrificial layers 136a-136i and lower insulating layers 104a-104j can be formed over a substrate 102. The lower sacrificial layers 136a-136i include an uppermost lower sacrificial layer 136i, a second lower sacrificial layer 136h under the uppermost lower sacrificial layer 136i, and third lower sacrificial layers 136a-136g under the second lower sacrificial layer 136h. The lower insulating layers 104a-104j can be made of SiO and the lower sacrificial layers 136a-136i can be made of SiN. In order to form the lower sacrificial layers and the lower insulating layers, any suitable deposition processes can be applied, such as a chemical vapor deposition (CVD), a physical vapor deposition (PVD), an atomic layer deposition (ALD), a thermal oxidation, an e-beam evaporation, a sputtering, a diffusion, or any combination thereof. In some embodiments, the uppermost lower sacrificial layer 136i can include a first doped dielectric region (e.g., 106i′ in FIG. 1A) and the second lower sacrificial layer 136h can include a second doped dielectric region (e.g., 106h′ in FIG. 1A). In some embodiments, the first doped dielectric region and the second doped dielectric region can be doped with carbon, boron, phosphorous, or other suitable dopants through an implantation process. Exemplary manufacturing steps to form the first dielectric region and the second dielectric region can be shown in FIGS. 15A-15C, 16A, 16B, 17A, 17B, 18A, and 18B.

In FIG. 4, a plurality of lower channel openings 140 can be formed. Each of the lower channel openings 140 can include sidewalls 140b extending through the lower sacrificial layers 136a-136i and the lower insulating layers 104a-104j, and a bottom 140a extending into the substrate 102. To form the lower channel openings 140, a mask layer (not shown) can be formed by a photolithography process and an etching process can subsequently be applied to form the lower channel openings 140 based on the mask layer. The lower channel openings 140 can have a tapered profile such that a CD of the bottom 140a is smaller than a CD of a top region 140c of the lower channel openings 140. Further, an upper stack 100B′ of alternating upper sacrificial layers 138a-138g and upper insulating layers 108a-108g can be formed over the lower stack 100A′. A plurality of upper channel openings 142 can be formed in the upper stack 100B′. Each of the upper channel openings 142 can include sidewalls 142b extending through the upper sacrificial layers and the upper insulating layers, and a bottom extending from a top region 104c of a respective lower channel opening 140. The upper channel openings 142 can have a tapered profile such that a CD of the bottom is smaller than a CD of a top region, where the top region can be level with an uppermost upper insulating layer 108g.

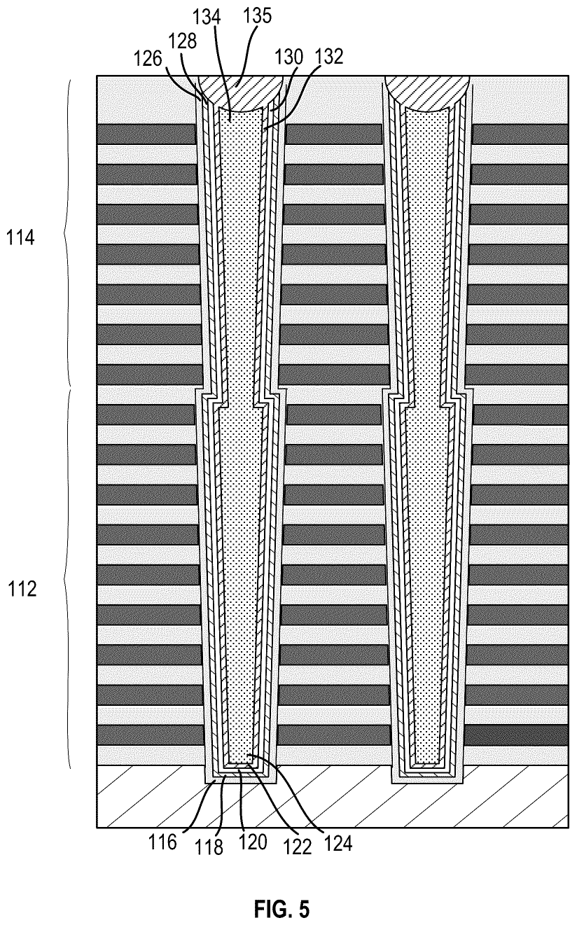

In FIG. 5, a first block layer 116 can be formed along sidewalls 140b and over the bottoms 140a of the lower channel openings 140, a first charge trapping layer 118 can be formed over the first block layer 116, a first tunneling layer 120 can be formed over the first charge trapping layer 118, and a first channel layer 122 can be formed over the first tunneling layer 120. Further, a first isolation layer 124 can be formed over the first channel layer 122. Accordingly, a plurality of lower channel structures 112 can be formed that can have similar features to the lower channel structures 112 in FIG. 1. Further, a second block layer 126 can be formed along sidewalls 142b of the upper channel openings 142 and in contact with the first block layer 116, a second charge trapping layer 128 formed over the second block layer 126 and in contact with the first charge trapping layer 118, a second tunneling layer 130 formed over the second charge trapping layer 128 and in contact with the first tunneling layer 120, and a second channel layer 132 formed over the second tunneling layer 130 and in contact with the first channel layer 122. In addition, a second isolation layer 134 can be formed along sidewalls of the second channel layer 132 and over the first isolation layer 124, and a channel contact 135 can be formed to contact the second channel layer 132 and be surrounded by the uppermost upper insulating layer 108g. Accordingly, a plurality of upper channel structures 114 can be formed that can have features similar to the upper channel structures 114 in FIG. 1.

In some embodiments, the layers of the upper channel structures and the layers of the lower channel structures can be formed using the same processes. For example, the first block layer 116 and the second block layer 126 can be formed through a same deposition process. In some embodiments, the layers of the upper channel structures and the layers of the lower channel structures can be formed in separate processes. Thus, the first block layer 116 can be formed at a first deposition process, and the second block layer 126 can be formed at a second deposition process.

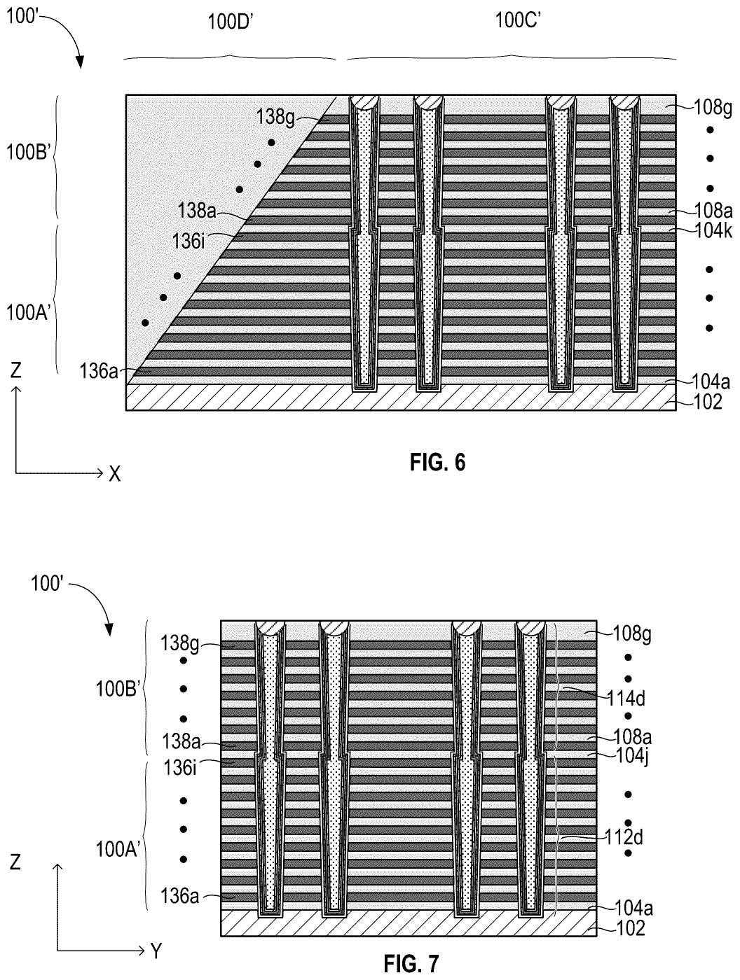

FIG. 6 shows a cross-sectional view of a semiconductor structure (or structure) 100′ obtained along the X direction. FIG. 7 shows a cross-sectional view of the structure 100′ obtained along the Y direction. As shown in FIGS. 6-7, The structure 100′ can include the lower stack 100A′, the upper stack 100B′ over the lower stack 100A′, the lower channel structures (e.g., 112d) formed in the lower stack 100A′, and the upper channel structures (e.g., 114d) formed in the upper stack 100B′ and positioned over the lower channel structures (e.g., 112d). The structure 100′ can include an array region 100C′ in which the lower channel structures and the upper channel structures are positioned, and a staircase region 100D′ that is positioned adjacent to and in contact with the array region 100C′.

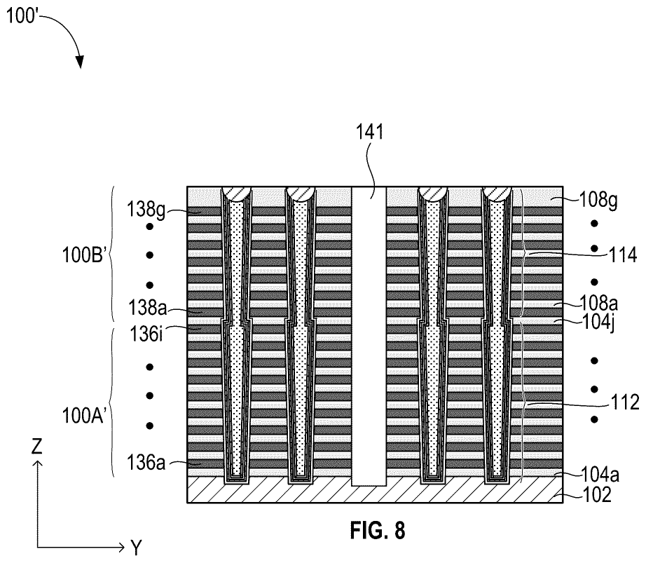

In FIG. 8, a trench opening 141 can be formed to extend through the lower stack 100A′ and the upper stack 100B′. The trench opening 141 can further extend into the substrate 102 in some embodiments. To form the trench opening 141, a mask with patterns (not shown) can be formed over the upper stack 100B′ by a photolithography process, and an etching process can subsequently be applied to transfer the patterns into the lower stack 100A′ and the upper stack 100B′ to form the trench opening 141.

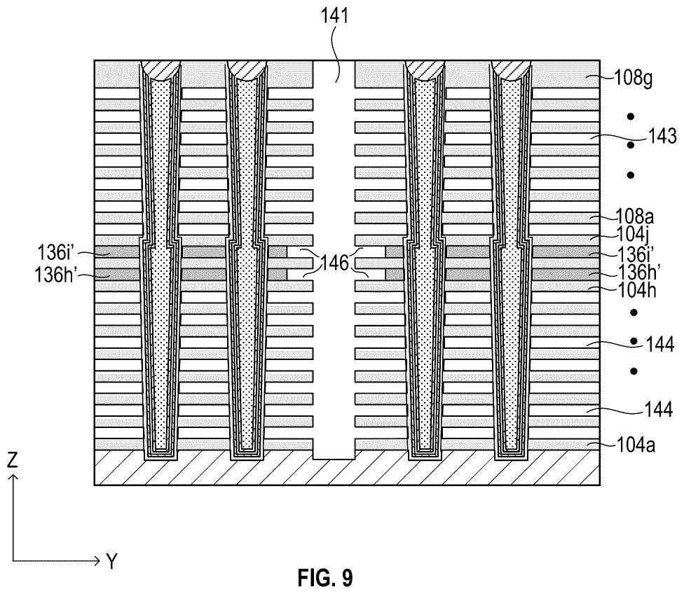

In FIG. 9, an etching chemistry, such as phosphoric acid, can be introduced from the trench opening 141 to remove the lower sacrificial layers 136a-136g and the upper sacrificial layers 138a-138g. The etching chemistry can be selective such that the lower and upper sacrificial layers are removed and the lower and upper insulating layers are unaffected. Etch rates of the first doped dielectric region 136i′ in the uppermost lower sacrificial layer 136i and the second doped dielectric region 136h′ in the second lower sacrificial layer 136h can be less than, and in some cases much less than, un-doped regions of the uppermost lower sacrificial layer 136i and the un-doped regions of the second lower sacrificial layer 136h. For example, the un-doped regions can have a 10 times larger etch rate than the first and second doped dielectric regions in the etching chemistry. Thus, the first doped dielectric region 136i′ and the second doped dielectric region 136h′ can still remain in the etching chemistry, and the un-doped regions of the uppermost lower sacrificial layer 136i and the second lower sacrificial layer 136h can be removed by the etching chemistry. When the lower sacrificial layers 136a-136g, the upper sacrificial layers 138a-138g, the un-doped regions of the uppermost lower sacrificial layer 136i and the second lower sacrificial layer 136h are removed, upper spaces 143 can be formed between the upper insulating layers 108a-108g in the array region 100C′ and the staircase region 100D′, first lower spaces (not shown) can be formed between the lower insulating layers 104a-104j in the staircase region 100D′, second lower spaces 144 can be formed between the lower insulating layers 104a-104h in the array region 100C′, and third lower spaces 146 can be formed between the uppermost lower insulating layer 104j and the third lower insulating layer 104h in the array region 100C′, and positioned between the trench opening 141 and the first and second doped dielectric regions 136i′ and 136h′.

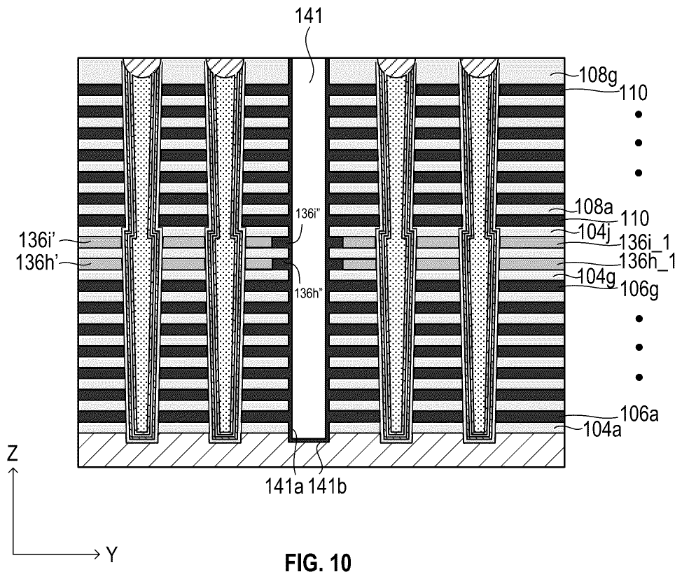

In FIG. 10, the upper spaces 143, the first lower spaces (not shown), the second lower spaces 144, and the third lower spaces 146 can be filled with a conductive material. Accordingly, upper word line layers 110 can be formed in the upper spaces 143 and arranged between the upper insulating layers 108a-108g. Lower word line layers 106a-106g can be formed in the second lower spaces 144 and arranged between the lower insulating layers 104a-104g. Further, a first intermediate layer 136i_1 and a second intermediate layer 136h_1 can be formed. The first intermediate layer 136i_1 can include the first doped dielectric region 136i′ and a first conductive region 136i″ that is formed in one of the third lower spaces 146. The second intermediate layer 136h_1 can include the second doped dielectric region 136h′ and a second conductive region 136h″ formed in another one of the third lower spaces 146. The conductive material can further be formed along sidewalls 141a and a bottom 141b of the trench opening 141. The conductive material can include W, Co, Ru, Co, or the like.

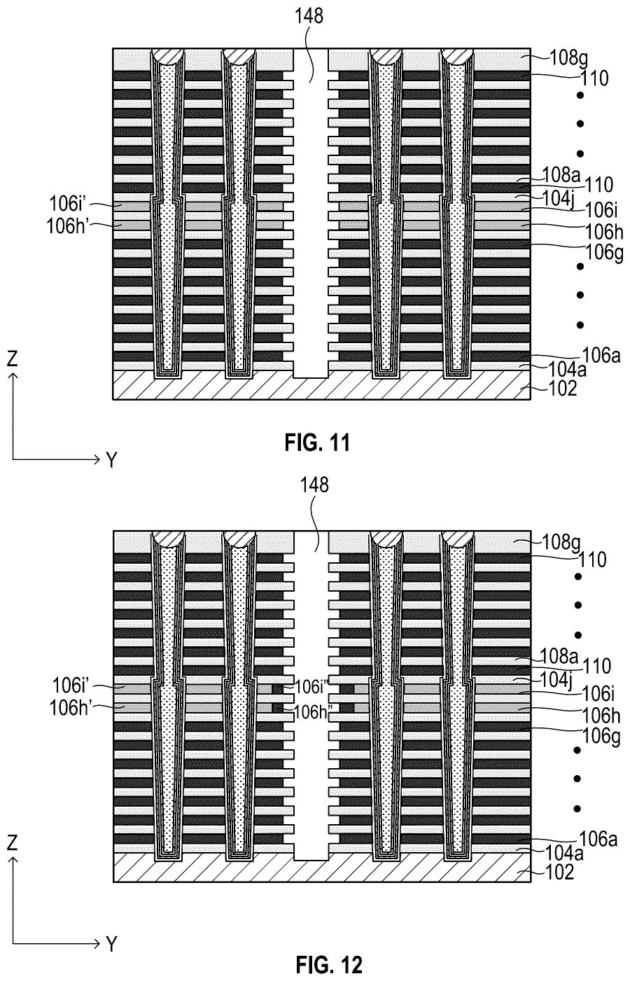

In FIG. 11, an etching process can be performed to remove the conductive material from the sidewalls 141a and the bottom 141b of the trench opening 141. The etching process can further remove the first conductive region 136i″ of the first intermediate layer 136i_1 and the second conductive region 136h″ of the second intermediate layer 136h_1. The etching process can also recess the lower word line layers 106a-106g and the upper word line layers 110 from the sidewalls 141a of the trench opening 141. When the first conductive region 136i″ and the second conductive region 136h″ are removed, the first intermediate layer 136i_1 becomes an uppermost lower word line layer (or first transition layer) 106i, and the second intermediate layer 136h_1 becomes a second lower word line layer (or second transition layer) 106h. Further, a slit opening 148 can be formed by the etching process. The slit opening 148 can extend from the substrate 102 and through the lower word line layers 106a-106i, the lower insulating layers 104a-104j, the upper word line layers 110, and the upper insulating layers 108a-108g in the vertical direction (e.g., Z direction) perpendicular to the substrate 102. The slit opening 148 can further extend into the upper word line layers 110 and the lower word line layers 106a-106i in the horizontal direction (e.g., Y direction) parallel to the substrate 102.

FIG. 12 shows another embodiment of the etching process to remove the conductive material. As shown in FIG. 12, when the etching process etches the first conductive region 136i″ of the first intermediate layer 136i_1 and the second conductive region 136h″ of the second intermediate layer 136h_1, the first conductive region 136i″ and the second conductive region 136h″ may not be removed fully. Thus, a portion of the first conductive region 136i″ and a portion of the second conductive region 136h″ can still remain. The remaining portion of the first conductive region 136i″ can become the first conductive portion 106i″ of the uppermost lower word line layer 106i, and the remaining portion of the second conductive region 136h″ can become the second conductive portion 106h″ of the second lower word line layer 106h.

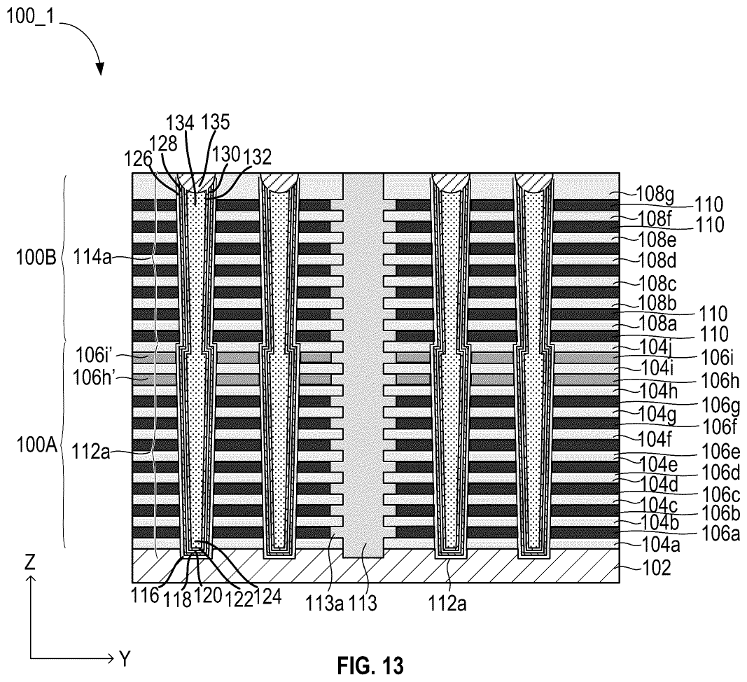

In FIG. 13, a dielectric material can be filled in the slit opening 148 that is shown in FIG. 11 to form a slit structure 113. The slit structure 113 can extend from the substrate 102 and through the lower word line layers 106a-106i, the lower insulating layers 104a-104j, the upper word line layers 110, and the upper insulating layers 108a-108g in the Z direction. The slit structure 113 can further include protrusions 113a that extend to and contact the upper word line layers 110, the lower word line layers 106a-106i in the Y direction. Accordingly, the slit structure 113 can be in contact with the first and second doped dielectric regions 136i′ and 136h′. When the slit structure 113 is formed, a 3D NAND memory device (or device) 100_1 can accordingly be formed. The device 100_1 can have features similar to the device 100_1 shown in FIG. 1A.

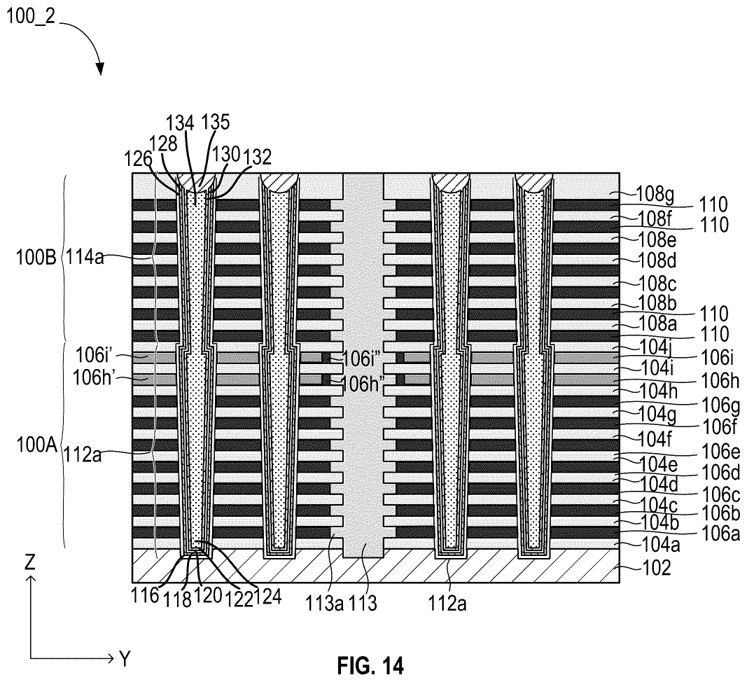

In FIG. 14, a dielectric material can be filled in the slit opening 148 that is shown in FIG. 12 to form a slit structure 113. The slit structure 113 can extend from the substrate 102 and through the lower word line layers 106a-106i, the lower insulating layers 104a-104j, the upper word line layers 110, and the upper insulating layers 108a-108g in the Z direction. The slit structure 113 can further include protrusions 113a that extend to and contact the upper word line layers 110 and the lower word line layers 106a-106i in the Y direction. Accordingly, the slit structure 113 can be in contact with the first and second conductive regions 136i″ and 136h″. When the slit structure 113 is formed, a 3D NAND memory device (or device) 100_2 can accordingly be formed. The device 100_2 can have features similar to the device 100_2 shown in FIG. 2A.

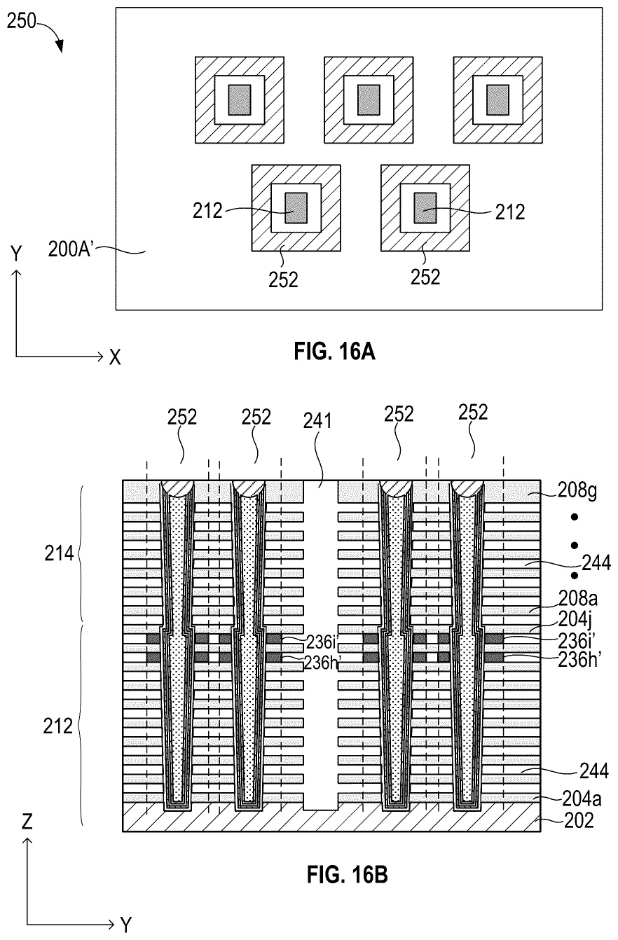

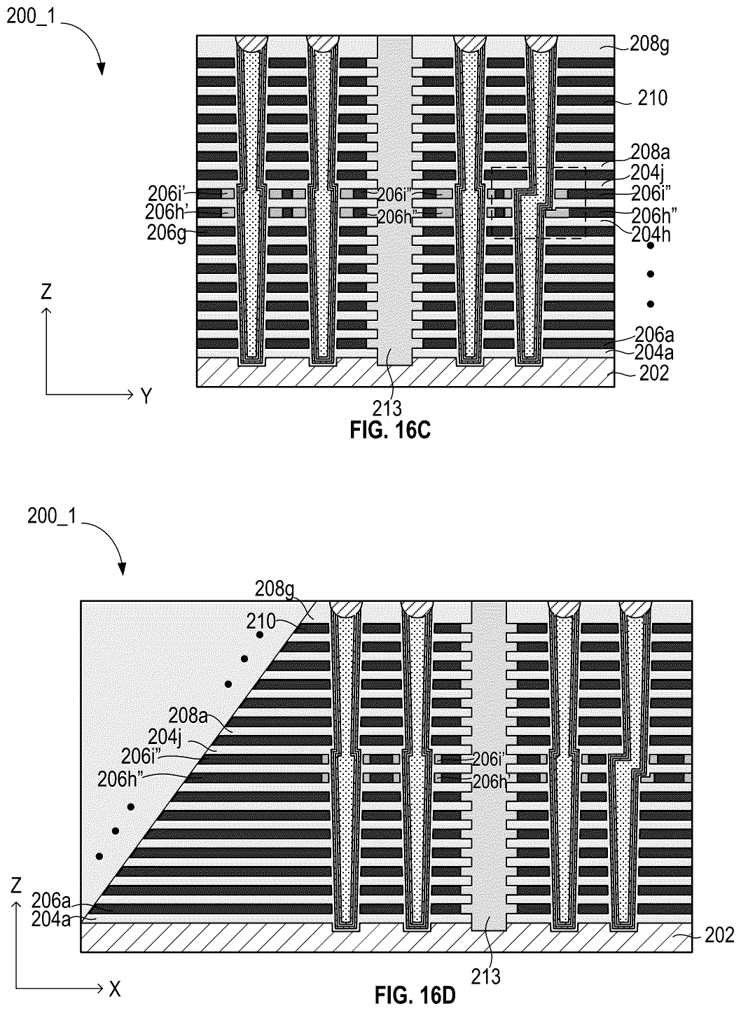

FIGS. 15A-15C, 16A, 16B, 16C, and 16D are cross-sectional views of various intermediate steps of manufacturing a first 3D NAND memory device 200_1 with doped dielectric regions in word line layers, in accordance with exemplary embodiments of the disclosure. As shown in FIG. 15A, a lower stack 200A is formed over a substrate 202. The lower stack 200A can include lower insulating layers 204a-204j and lower sacrificial layers 236a-236i that are alternatingly stacked over the substrate 202. In FIG. 15B, a mask layer 250 can be formed over a top surface 200A′ of the lower stack 200A. The mask layer 250 can be formed through a photolithography process and include patterns 252 that uncover portions of a top surface of the lower stack 200A. In FIG. 15C, an implantation process 254 can be performed to inject dopants, such as C, B, or P, into the uppermost lower sacrificial layer 236i and the second lower sacrificial layer 236h through the uncovered regions of the lower stack 200A to form a first doped dielectric region in the uppermost lower sacrificial layer 236i and a second doped dielectric region in the second lower sacrificial layer 236h.

FIG. 16A is a top down view of a first layout of the mask layer 250. As shown in FIG. 16A, the mask layer 250 can include patterns 252 that uncover portions of the top surface 200A′ of the lower stack 200A. The uncovered portions can be disposed around the lower channel structures 212. An implantation process 254 can subsequently be applied to dope the uppermost lower sacrificial layer 236i and the second lower sacrificial layer 236h through the uncovered portions to form a plurality of first doped dielectric portions 236i′ in the uppermost lower sacrificial layer 236i and a plurality of second doped dielectric portions 236h′ in the second lower sacrificial layer 236h.

In FIG. 16B, an etching chemistry, such as phosphoric acid, can be introduced from the trench opening 241 to remove the lower sacrificial layers 236a-236g and the upper sacrificial layers, and un-doped regions of the uppermost lower sacrificial layer 236i and the second lower sacrificial layer 236h to form spaces 244 between the lower insulating layers 204a-204j and the upper insulating layers 208a-208g. The first doped dielectric portions 236i′ and the second doped dielectric portions 236h′ can remain.

In FIGS. 16C and 16D, a conductive material can be deposited to fill the spaces 244. The conductive material positioned between the upper insulating layers 208a-208g can become upper word line layers 210. The conductive material positioned between the lower insulating layers 204h-204j, the first doped dielectric portions 236i′, and the second doped dielectric portions 236h′ can form an uppermost lower word line layer 206h and a second lower word line layer 206i respectively. Accordingly, the first doped dielectric portions 236i′ become first doped dielectric portions 206i′, and the second doped dielectric portions 236h′ become second doped dielectric portions 206h′.

The conductive material positioned between the lower insulating layers 204a-204h can become lower word line layers 206a-206g. Further, a dielectric layer can be filled in the trench opening 241 to form the slit structure 213. Accordingly, a device 200_1 can be formed. In the device 200_1, the uppermost lower word line layer 206i can include the first doped dielectric portions 206i′ that are positioned between the conductive portions 206i″, and the second lower word line layer 206h can include the second doped dielectric portions 206h′ that are positioned between the conductive portions 206h″. The channel structures 112 can extend through the first doped dielectric portions 206i′ and the second doped dielectric portions 206h′.

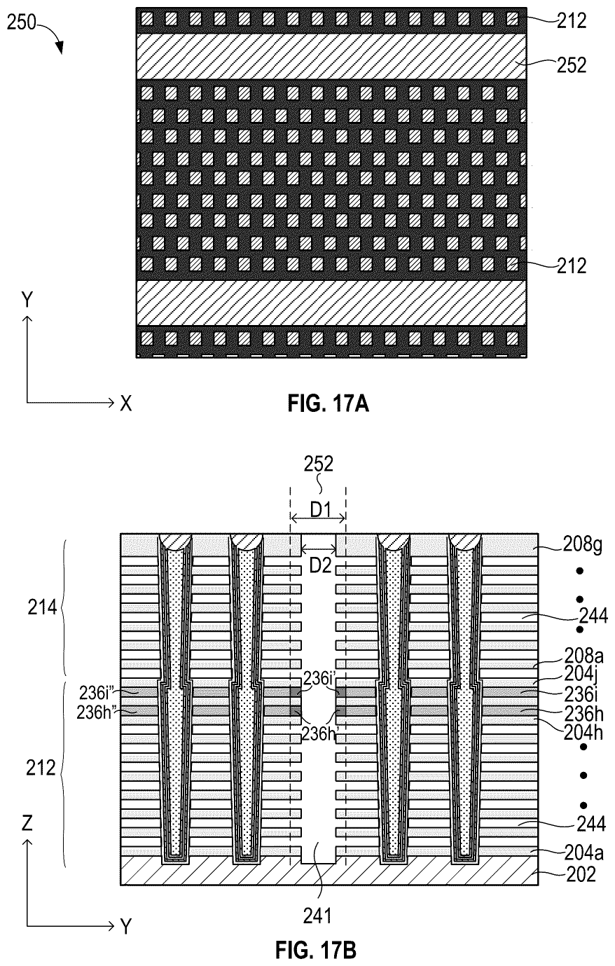

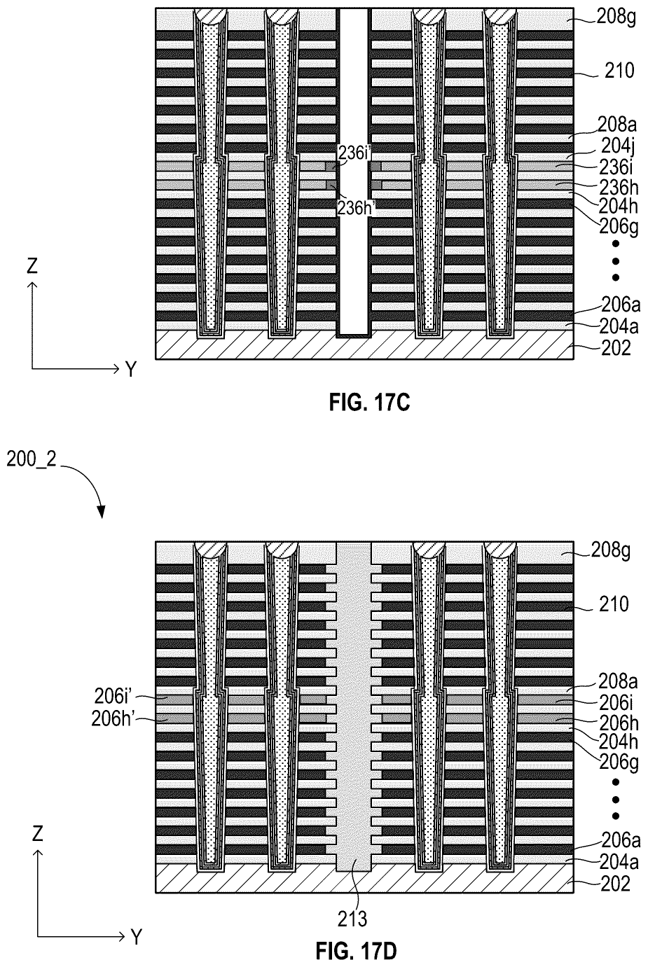

FIGS. 15A-15C, 17A, 17B, 17C, and 17D are cross-sectional views of various intermediate steps of manufacturing a second 3D NAND memory device 200_2 with doped dielectric regions in word line layers, in accordance with exemplary embodiments of the disclosure. The manufacturing steps can start with FIGS. 15A-15C, and then proceed to FIG. 17A. FIG. 17A shows a top down view of a second layout of the mask layer 250. As shown in FIG. 17A, the mask layer 250 can include patterns 252 that are disposed along a slit structure (e.g., 213) to uncover the slit structure. In some embodiments, a CD D1 of the patterns 252 can be larger than a CD D2 of the slit structure. An implantation process (e.g., 254) can subsequently be applied to dope the uppermost lower sacrificial layer 236i and the second lower sacrificial layer 236h through the uncovered portions to form a first doped dielectric portion 236i′ in the uppermost lower sacrificial layer 236i and a second doped dielectric portions 236h′ in the second lower sacrificial layer 236h.

In FIG. 17B, an etching chemistry, such as phosphoric acid, can be introduced from the trench opening 241 to remove the lower sacrificial layers 236a-236g and the upper sacrificial layers. Un-doped portions 236i″ and 236h″ of the uppermost lower sacrificial layer 236i and the second lower sacrificial layer 236h can be blocked by the first doped dielectric portion 236i′ and the second doped dielectric portion 236h′ from reaching the etching chemistry positioned in the trench opening 241. Thus, the uppermost lower sacrificial layer 236i and second lower sacrificial layer 236h can remain. Spaces 244 can be formed between the lower insulating layers 204a-204h and the upper insulating layers 208a-208g.

In FIG. 17C, a conductive material can be deposited to fill the spaces 244 to form upper word line layers 210 and lower word line layers 206a-206g. In FIG. 17D, an etching process can be performed to remove the conductive material positioned along sidewalls and a bottom of the trench opening 241. The etching process can further recess the upper word line layers 210 and the lower word line layers 206a-206g. The etching process can also recess the uppermost lower sacrificial layer 236i and the second lower sacrificial layer 236h to remove at least portions of the first doped dielectric portion 236i′ and the second doped dielectric portion 236h′. The remaining uppermost lower sacrificial layer 236i and the second lower sacrificial layer 236h can become lower word line layers 206i and 206h. A dielectric layer can subsequently be filled in the trench opening 241 to form the slit structure 213. When the slit structure 213 is formed, a device 200_2 can be formed accordingly that has features similar to the device 100_1 in FIG. 1A.

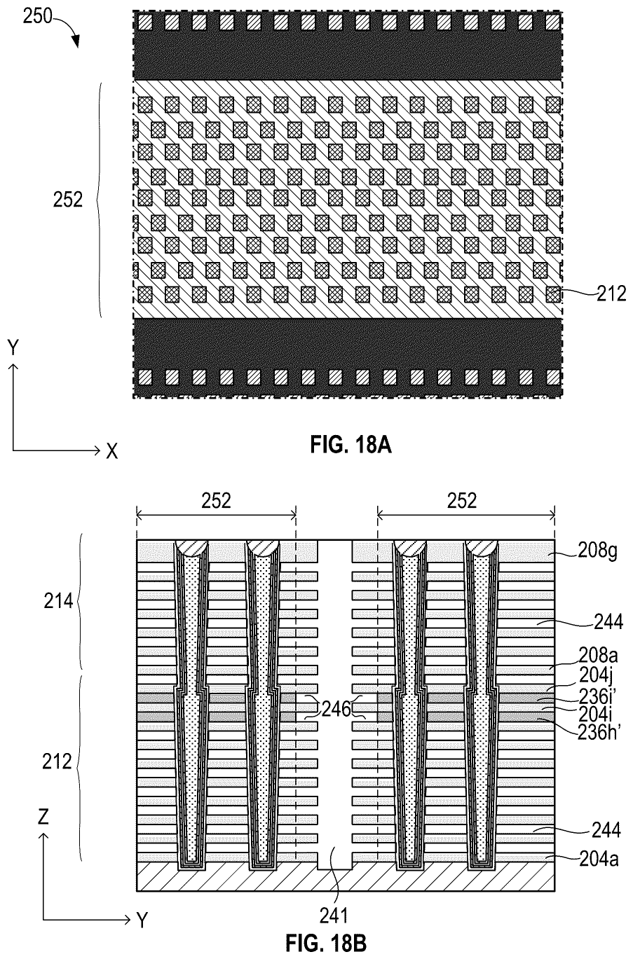

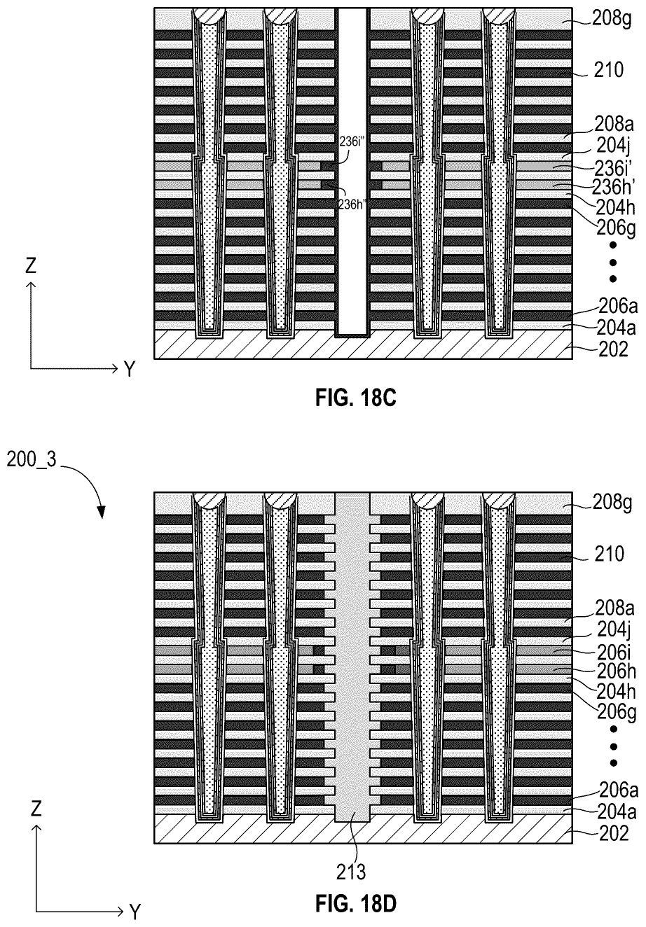

FIGS. 15A-15C and 18A-18D are cross-sectional views of various intermediate steps of manufacturing a third 3D NAND memory device 200_3 with doped dielectric regions in word line layers, in accordance with exemplary embodiments of the disclosure. The manufacturing steps can start with FIGS. 15A-15C, and then proceed to FIG. 18A. FIG. 18A shows a top down view of a third layout of the mask layer 250. As shown in FIG. 18A, the mask layer 250 can include patterns 252 that uncover all lower channel structures 212 in the array region. The implantation process 254 can subsequently be applied to dope the uppermost lower sacrificial layer 236i and the second lower sacrificial layer 236h through the uncovered portions to form a plurality of first doped dielectric portions 236i′ in the uppermost lower sacrificial layer 236i and a plurality of second doped dielectric portions 236h′ in the second lower sacrificial layer 236h.

In FIG. 18B, an etching chemistry, such as phosphoric acid, can be introduced from the trench opening 241 to remove the lower sacrificial layers 236a-236g and the upper sacrificial layers. The first doped dielectric portion 236i′ and the second doped dielectric portion 236h′ can still remain. Spaces 244 and 246 can be formed between the lower insulating layers 204a-204j and the upper insulating layers 208a-208g. In FIG. 18C, a conductive material can be deposited to fill the spaces 244 to form upper word line layers 210 and lower word line layers 206a-206g. The conductive material can also be positioned in the spaces 246 to form conductive portions 236i″ and 236h″ in the spaces 246. In FIG. 18D, an etching process can be performed to remove the conductive material positioned along sidewalls and a bottom of the trench opening 241. The etching process can further recess the upper word line layers 210 and the lower word line layers 206a-206g. The etching process can also recess the uppermost lower sacrificial layer 236i and the second lower sacrificial layer 236h to remove at least portions of the conductive portions 236i″ and 236h″. The remaining uppermost lower sacrificial layer 236i and the second lower sacrificial layer 236h can become lower word line layers 206i and 206h. A dielectric layer can subsequently be filled in the trench opening 241 to form the slit structure 213. When the slit structure 213 is formed, a device 200_3 can be formed accordingly that has features similar to the device 100_2 in FIG. 2A.

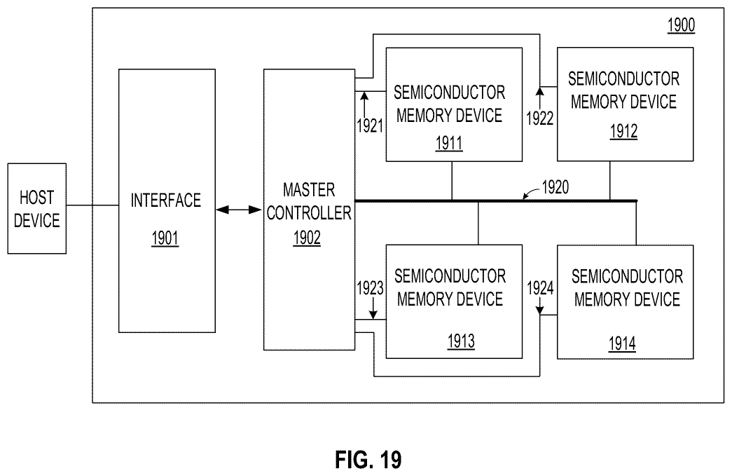

FIG. 19 shows a block diagram of a memory system device 1900 according to some examples of the disclosure. The memory system device 1900 includes one or more semiconductor memory devices, such as shown by semiconductor memory devices 1911-1914, that can be respectively configured similarly as the device 100_1 or 100_2. In some examples, the memory system device 1900 is a solid state drive (SSD) or a memory module.

The memory system device 1900 can include other suitable components. For example, the memory system device 1900 includes an interface (or master interface circuitry) 1901 and a master controller (or master control circuitry) 1902 coupled together as shown in FIG. 19. The memory system device 1900 can include a bus 1920 that couples the master controller 1902 with the semiconductor memory devices 1911-1914. In addition, the master controller 1902 is connected with the semiconductor memory devices 1911-1914 respectively, such as shown by respective control lines 1921-1924.

The interface 1901 is suitably configured mechanically and electrically to connect between the memory system device 1900 and a host device, and can be used to transfer data between the memory system device 1900 and the host device.

The master controller 1902 is configured to connect the respective semiconductor memory devices 1911-1914 to the interface 1901 for data transfer. For example, the master controller 1902 is configured to provide enable/disable signals respectively to the semiconductor memory devices 1911-1914 to activate one or more semiconductor memory devices 1911-1914 for data transfer.

The master controller 1902 is responsible for the completion of various instructions within the memory system device 1900. For example, the master controller 1902 can perform bad block management, error checking and correction, garbage collection, and the like. In some embodiments, the master controller 1902 is implemented using a processor chip. In some examples, the master controller 1902 is implemented using multiple MCUs.

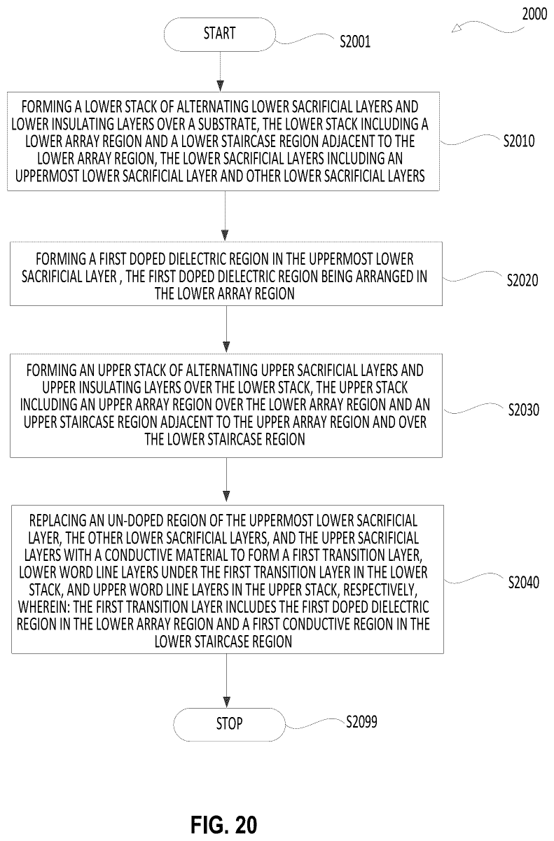

FIG. 20 is a flowchart of an exemplary process 2000 for fabricating a 3D NAND memory device. The process 2000 begins at S2001, and then proceeds to S2010. At S2010, a lower stack of alternating lower sacrificial layers and lower insulating layers can be formed over a substrate, where the lower stack can include a lower array region and a lower staircase region adjacent to the lower array region. The lower sacrificial layers can include an uppermost lower sacrificial layer and other lower sacrificial layers under the uppermost lower sacrificial layers. In some embodiments, S2010 can be performed as illustrated with reference to FIG. 3.

At S2020, a first doped dielectric region can be formed in the uppermost lower sacrificial layer, where the first doped dielectric region can be arranged in the lower array region. In some embodiments, S2030 can be performed as illustrated with reference to FIG. 15A-15C and 16A, 17A, or 18A.

At S2030, an upper stack of alternating upper sacrificial layers and upper insulating layers can be formed over the lower stack, where the upper stack can include an upper array region over the lower array region and an upper staircase region adjacent to the upper array region and over the lower staircase region. In some embodiments, S2030 can be performed as illustrated with reference to FIG. 4.

At S2040, an un-doped region of the uppermost lower sacrificial layer, the other lower sacrificial layers, and the upper sacrificial layers can be replaced with a conductive material to form a first transition layer, lower word line layers under the first transition layer in the lower stack, and upper word line layers in the upper stack. Accordingly, the first transition layer can include the first doped dielectric region in the lower array region and a first conductive region in the lower staircase region. In some embodiments, S2040 can be performed as illustrated with reference to FIGS. 8-14.

In some embodiments, the lower stack can further include a second lower sacrificial layer between the uppermost lower sacrificial layer and the other lower sacrificial layers. Thus, in the method, a second doped dielectric region can be formed in the second lower sacrificial layer, where the second doped dielectric region can be positioned under the first doped dielectric region and arranged in the lower array region. An un-doped region of the second lower sacrificial layer can be replaced with the conductive material to form a second transition layer, where the second transition layer can include the second doped dielectric region in the lower array region and a second conductive region in the lower staircase region.

In the process 2000, as shown in FIG. 5, a lower channel structure can be formed to extend from the substrate and through the lower array region of the lower stack. The lower channel structure can extend through the first and second doped dielectric regions. An upper channel structure can be formed to extend from the lower channel structure and through the upper array region of the upper stack.

To replace the un-doped region of the uppermost lower sacrificial layer, as shown in FIGS. 8-10, the other lower sacrificial layers, and the upper sacrificial layers with the conductive material, a trench opening can be formed. The trench opening can have a bottom extending into the substrate and sidewalls extending through the lower stack and the upper stack. An etching chemistry can be introduced from the trench opening to remove the un-doped region of the uppermost lower sacrificial layer, the un-doped region of the second lower sacrificial layer, the other lower sacrificial layers, and the upper sacrificial layers. Spaces can subsequently be formed between two adjacent insulating layers of the lower insulating layers and the upper insulating layers. The conductive material can be deposited in the spaces to form the first conductive region of the first transition layer, the second conductive region of the second transition layer, the lower word line layers in the lower stack, and the upper word line layers in the upper stack. The conductive material can further be deposited along the sidewalls and over the bottom of the trench opening.

In the process 2000, as shown in FIGS. 11 and 12, an etching process can subsequently be applied to remove the conductive material deposited along sidewalls and over the bottom of the trench opening to form a slit opening. The etching process can further recess the first transition layer, the second transition layer, the lower word line layers, and the upper word line layers from the sidewalls of the trench opening in a horizontal direction parallel to the substrate. Accordingly, the slit opening can extend into the first transition layer, the second transition layer, the lower word line layers, and the upper word line layer. A dielectric material can be deposited to fill in the slit opening to form a slit structure.

In the process 2000, as shown in FIGS. 13 and 14, the slit structure can extend from the substrate, through the lower insulating layers and the upper insulating layers, and further include protrusions that extend to and contact the first doped dielectric region of the first transition layer, the second doped dielectric region of the second transition layer, the lower word line layers, and the upper word line layers in the horizontal direction.

In some embodiments, as shown in FIG. 12, the conductive material can be deposited in the spaces to form (i) a third conductive region of the first transition layer in the lower array region and arranged between the first doped dielectric region and the slit structure, and (ii) a fourth conductive region of the second transition layer in the lower array region and arranged between the second doped dielectric region and the slit structure. Accordingly, the protrusions of the slit structure can extend to and contact the third conductive region of the first transition layer and the fourth conductive region of the second transition layer in the horizontal direction.

In some embodiments, as shown in FIG. 16C, the conductive material can be deposited in the spaces to form (i) a fifth conductive region of the first transition layer in the lower array region such that the first doped dielectric region is arranged between the third and fifth conductive regions, and (ii) a sixth conductive region of the second transition layer in the lower array region such that the second doped dielectric region is arranged between the fourth and sixth conductive regions.

To form the first doped dielectric region and the second doped dielectric region, as shown in FIGS. 15A-15C, a mask layer can be formed over a top surface of the lower stack. The mask layer can include a pattern to uncover an implant region of the top surface of the lower stack in the lower array region. An implantation process can be performed to inject dopants into the uppermost lower sacrificial layer and the second lower sacrificial layer through the implant region of the lower stack to form the first doped dielectric region and the second doped dielectric region.

In some embodiments, as shown in FIGS. 16A, 17A, and 18A, the implant region of the lower stack can include one of (i) a first region around the lower channel structure, (ii) a second region uncovering the slit structure, and (iii) a third region uncovering the lower array region.

It should be noted that additional steps can be provided before, during, and after the process 2000, and some of the steps described can be replaced, eliminated, or performed in different order for additional embodiments of the process 2000. For example, dummy channel structures can be formed in the staircase region. A plurality of word line contacts can further be formed to extend from the lower word line layers and the upper word line layers in the staircase region. In subsequent process steps, various additional interconnect structures (e.g., metallization layers having conductive lines and/or VIAs) may be formed over the 3D NAND memory device (e.g., 100). Such interconnect structures electrically connect the 3D NAND memory device with other contact structures and/or active devices to form functional circuits. Additional device features such as passivation layers, input/output structures, and the like may also be formed.

The various embodiments described herein offer several advantages over related examples. For example, in the disclosure, dielectric regions can be formed in the lower word line layers (e.g., an uppermost lower word line layer) that are positioned at an interface (or joint) area of the upper channel structures and the lower channel structures. When the poor overlap occurs between the upper channel structure and the lower channel structure, the upper channel structure can extend into the dielectric regions of the adjacent lower word line layers rather than conductive regions of the adjacent lower word line layers. Thus, voids in the adjacent word lines can be prevented. Accordingly, an electrical leakage in the adjacent lower word line layers or an electrical short between the upper channel structure and the adjacent lower word line layers can be prevented.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first stack of alternating first word line layers and first insulating layers over a semiconductor layer, the first stack including a first array region and a first staircase region adjacent to the first array region;
a first channel structure extending from the semiconductor layer and through the first array region of the first stack;
a second stack of alternating second word line layers and second insulating layers over the first stack, the second stack including a second array region over the first array region and a second staircase region adjacent to the second array region and over the first staircase region; and
a second channel structure extending from the first channel structure and through the second array region of the second stack, wherein:
the first stack further includes a first transition layer over the first word line layers, the first transition layer including a first dielectric portion in the first array region that surrounds the first channel structure and a first conductive portion, the first transition layer being disposed between two adjacent first insulating layers of the first insulating layers.

2. The semiconductor device of claim 1, wherein the first conductive portion is in the first staircase region.

3. The semiconductor device of claim 1, wherein the first conductive portion is in the first array region.

4. The semiconductor device of claim 1, further comprising:
a slit structure extending through the first stack and the second stack in a vertical direction perpendicular to the semiconductor layer.

5. The semiconductor device of claim 4, wherein the first transition layer further includes a second conductive portion positioned in the first array region and arranged between the first dielectric portion and the slit structure, and the slit structure includes protrusions that extend to and contact the first transition layer, the first word line layers, and the second word line layers in a horizontal direction parallel to the semiconductor layer.

6. The semiconductor device of claim 5, wherein the first transition layer further includes a third conductive portion positioned in the first array region and sandwiched by the first dielectric portion.

7. The semiconductor device of claim 5, wherein the slit structure includes protrusions that extend to the second dielectric portion of the first transition layer in the horizontal direction.

8. The semiconductor device of claim 4, wherein the slit structure includes protrusions that extend to the first dielectric portion of the first transition layer in the horizontal direction.

9. The semiconductor device of claim 3, wherein the first stack further includes a second transition layer that is positioned between the first transition layer and the first word line layers, the second transition layer including a second dielectric portion under the first dielectric portion in the first array region that surrounds the first channel structure and a first conductive portion in the first staircase region.

10. The semiconductor device of claim 1, wherein the first dielectric portion of the first transition layer includes nitride.

11. The semiconductor device of claim 10, wherein the first dielectric portion of the first transition layer is doped with one of carbon, boron and phosphorous.

12. A method of manufacturing a semiconductor device, comprising:
forming a first stack of alternating first sacrificial layers and first insulating layers over a semiconductor layer, the first stack including a first array region and a first staircase region adjacent to the first array region, the first sacrificial layers including an uppermost first sacrificial layer and other first sacrificial layers;
forming a first region in the uppermost first sacrificial layer;
forming a second stack of alternating second sacrificial layers and second insulating layers over the first stack, the second stack including a second array region over the first array region and a second staircase region adjacent to the second array region and over the first staircase region; and
replacing a second region of the uppermost first sacrificial layer, the other first sacrificial layers, and the second sacrificial layers with a conductive material to form a first transition layer, first word line layers under the first transition layer in the first stack, and second word line layers in the second stack, respectively, wherein:
the first transition layer includes the first region in the first array region and a first conductive region.

13. The method of claim 12, wherein the first conductive region is in the first staircase region.

14. The method of claim 12, wherein the first conductive region is in the first array region.

15. The method of claim 12, where the first stack further includes a secondary first sacrificial layer between the uppermost first sacrificial layer and the other first sacrificial layers, the method further comprising:
forming a third region in the secondary first sacrificial layer, the third region being positioned under the first region and arranged in the first array region; and
replacing a fourth region of the secondary first sacrificial layer with the conductive material to form a second transition layer, the second transition layer including the third region in the first array region and a second conductive region.

16. The method of claim 15, further comprising:
forming a first channel structure extending from the semiconductor layer and through the first array region of the first stack such that the first channel structure extends through the first and third regions; and
forming a second channel structure extending from the first channel structure and through the second array region of the second stack.

17. The method of claim 15, wherein the replacing the second region of the uppermost first sacrificial layer, the other first sacrificial layers, the second sacrificial layers, and the fourth region of the secondary first sacrificial layer further comprise:
forming a trench opening having a bottom extending into the semiconductor layer;
removing the second region of the uppermost first sacrificial layer, the fourth region of the secondary first sacrificial layer, the other first sacrificial layers, and the second sacrificial layers such that spaces are formed between adjacent insulating layers of the first insulating layers and the second insulating layers; and
depositing the conductive material in the spaces to form the first conductive region of the first transition layer, the second conductive region of the second transition layer, the first word line layers in the first stack, and the second word line layers in the second stack, the conductive material further being deposited along sidewalls of the trench opening and over the bottom of the trench opening.

18. The method of claim 17, further comprising:
removing the conductive material deposited along the sidewalls and over the bottom of the trench opening to form a slit opening, and recessing the first transition layer, the second transition layer, the first word line layers, and the second word line layers from the sidewalls of the trench opening in a horizontal direction parallel to the semiconductor layer such that the slit opening extends to the first transition layer, the second transition layer, the first word line layers, and the second word line layers; and
depositing a dielectric material to fill in the slit opening to form a slit structure.

19. The method of claim 18, wherein the slit structure extends through the first insulating layers and the second insulating layers, and further includes protrusions that extend to and contact the first region of the first transition layer, the third region of the second transition layer, the first word line layers, and the second word line layers in the horizontal direction.

20. The method of claim 18, wherein the replacing the second region of the uppermost first sacrificial layer and the fourth region of the secondary first sacrificial layer further comprise:
depositing the conductive material in the spaces to form (i) a third conductive region of the first transition layer in the first array region and arranged between the first region and the slit structure, and (ii) a fourth conductive region of the second transition layer in the first array region and arranged between the third region and the slit structure, wherein:
the slit structure includes protrusions that extend to and contact the third conductive region of the first transition layer and the fourth conductive region of the second transition layer in the horizontal direction.

21. The method of claim 20, wherein the replacing further comprises:
depositing the conductive material in the spaces to form (i) a fifth conductive region of the first transition layer in the first array region such that the first region is arranged between the third and fifth conductive regions, and (ii) a sixth conductive region of the second transition layer in the first array region such that the third region is arranged between the fourth and sixth conductive regions.

22. The method of claim 18, wherein the forming the first region and the third region further comprise:
forming a mask layer over a top surface of the first stack, the mask layer including a pattern to uncover an implant region of the top surface of the first stack in the first array region; and
performing an implantation process to inject dopants into the uppermost first sacrificial layer and the secondary first sacrificial layer through the implant region of the first stack to form the first region and the third region.

23. The method of claim 21, wherein the implant region of the first stack includes one of (i) a first region around the first channel structure, (ii) a second region uncovering the slit structure, and (iii) a third region uncovering the first array region.

24. A memory system device, comprising:
a control circuitry coupled with a memory device; and
the memory device comprising:
first stack of alternating first word line layers and first insulating layers over a semiconductor layer, the first stack including a first array region and a first staircase region adjacent to the first array region;
a first channel structure extending from the semiconductor layer and through the first array region of the first stack;
a second stack of alternating second word line layers and second insulating layers over the first stack, the second stack including a second array region over the first array region and a second staircase region adjacent to the second array region and over the first staircase region; and
a second channel structure extending from the first channel structure and through the second array region of the second stack, wherein:
the first stack further includes a first transition layer over the first word line layers, the first transition layer including a first dielectric portion in the first array region that surrounds the first channel structure and a first conductive portion, the first transition layer being disposed between two adjacent first insulating layers of the first insulating layers.
